(19) United States
(12) Patent Application Publication
(10) Pub. No.: US 2026/0178072 A1
(43) Pub. Date: Jun. 25, 2026

(54) TIME BORROWING TECHNIQUES IN CACHE MEMORY TIMING PATHS

(71) Applicant: QUALCOMM Incorporated, San Diego, CA (US)

(72) Inventors: Vivek DHOGALE, Bangalore (IN); Raashid Moin SHAIKH, Bangalore (IN)

(21) Appl. No.: 18/991,212

(22) Filed: Dec. 20, 2024

(51) Int. Cl. G06F 1/06; G06F 12/0811

(52) U.S. Cl. CPC G06F 1/06; G06F 12/0811; G06F 2212/60

(57) ABSTRACT

A method for time borrowing in memory timing paths of a memory is described. The method includes holding memory input data in a latch buffer according to a core clock. The method also includes delaying the core clock to generate a memory clock. The method further includes feeding the memory input data from the latch buffer to a memory input of the memory according to the memory clock. The method also includes accessing a memory output of the memory according to the core clock.

### BACKGROUND

### Field

Aspects of the present disclosure relate to semiconductor devices and, more particularly, to a time borrowing techniques in cache memory timing paths.

### Background

Semiconductor memory devices include, for example, static random-access memory (SRAM) and dynamic random-access memory (DRAM). A DRAM memory cell includes one transistor and one capacitor, thereby providing a high degree of integration. DRAM, however, requires constant refreshing, which limits the use of DRAM to computer main memory. An SRAM memory cell, by contrast, is bi-stable, meaning that it can maintain its state statically and indefinitely, so long as adequate power is supplied. SRAM also supports high speed operation, with lower power dissipation, which is useful for implementing computer cache memory.

Operation of processor architectures involves fetching data from memory, performing certain arithmetic operations, logical operations, etc., and storing the data back into the memory. In practice, multi-level cache architectures are commonly employed for improved performance by exploiting a spatial locality and a temporal locality of the accessed data. For example, the multi-level cache architecture may include a level-one (L1) cache, a level-two (L2) cache, and a level-three (L3) cache. L2/L3 cache memories are commonly implemented using large-size memories (e.g., SRAM), which are accessed using multi-cycle modes. These multi-cycle modes may specify a single cycle setup time on memory input pins of the L2/L3 cache memories. Unfortunately, meeting the single cycle setup time on the input pins of the cache memories is challenging and often limits memory frequency.

Accordingly, there is a need for time borrowing techniques for cache memory timing paths.

### SUMMARY

A method for time borrowing in memory timing paths of a memory is described. The method includes holding memory input data in a latch buffer according to a core clock. The method also includes delaying the core clock to generate a memory clock. The method further includes feeding the memory input data from the latch buffer to a memory input of the memory according to the memory clock. The method also includes accessing a memory output of the memory according to the core clock.

A non-transitory computer-readable medium having program code recorded thereon for time borrowing in memory timing paths of a memory is described. The program code is executed by a processor. The non-transitory computer-readable medium includes program code to hold memory input data in a latch buffer according to a core clock. The non-transitory computer-readable medium also includes program code to delay the core clock to generate a memory clock. The non-transitory computer-readable medium further includes program code to feed the memory input data from the latch buffer to a memory input of the memory according to the memory clock. The non-transitory computer-readable medium also includes program code to access a memory output of the memory according to the core clock.

This has outlined, broadly, the features and technical advantages of the present disclosure in order that the detailed description that follows may be better understood. Additional features and advantages of the present disclosure will be described below. It should be appreciated by those skilled in the art that this present disclosure may be readily utilized as a basis for modifying or designing other structures for conducting the same purposes of the present disclosure. It should also be realized by those skilled in the art that such equivalent constructions do not depart from the teachings of the present disclosure as set forth in the appended claims. The novel features, which are believed to be characteristic of the present disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 illustrates an example implementation of a system-on-chip (SoC), which includes a memory system configured according to a time borrowing memory design, in accordance with aspects of the present disclosure.

FIG. 2 is a block diagram illustrating a memory system configured according to a time borrowing memory design, in accordance with various aspects of the present disclosure.

FIGS. 3A and 3B are timing diagrams illustrating time borrowing in cache memory timing paths of the memory system of FIG. 2, according to various aspects of the present disclosure.

FIGS. 4A and 4B are timing diagrams illustrating time borrowing in cache memory timing paths of the memory system of FIG. 2, according to various aspects of the present disclosure.

FIG. 5 is a timing diagram illustrating time borrowing in cache memory timing paths of the memory system of FIG. 2, in accordance with various aspects of the present disclosure.

FIG. 6 is a process flow diagram illustrating a method for time borrowing in cache memory timing paths of a memory system, according to various aspects of the present disclosure.

FIG. 7 is a block diagram showing an exemplary wireless communications system in which a configuration of the disclosure may be advantageously employed.

FIG. 8 is a block diagram illustrating a design workstation used for circuit, layout, and logic design of a semiconductor component, such as the memory system configured according to a time borrowing memory design.

### DETAILED DESCRIPTION

The detailed description set forth below, in connection with the appended drawings, is intended as a description of various configurations and is not intended to represent the only configurations in which the concepts described may be practiced. The detailed description includes specific details for the purpose of providing a thorough understanding of the various concepts. It will be apparent, however, to those skilled in the art that these concepts may be practiced without these specific details. In some instances, well-known structures and components are shown in block diagram form to avoid obscuring such concepts.

As described, the use of the term “and/or” is intended to represent an “inclusive OR,” and the use of the term “or” is intended to represent an “exclusive OR.” As described, the term “exemplary” used throughout this description means “serving as an example, instance, or illustration,” and should not necessarily be construed as preferred or advantageous over other exemplary configurations. As described, the term “coupled” used throughout this description means “connected, whether directly or indirectly through intervening connections (e.g., a switch), electrical, mechanical, or otherwise,” and is not necessarily limited to physical connections. Additionally, the connections can be such that the objects are permanently connected or releasably connected. The connections can be through switches. As described, the term “proximate” used throughout this description means “adjacent, very near, next to, or close to.” As described, the term “on” used throughout this description means “directly on” in some configurations, and “indirectly on” in other configurations.

Semiconductor memory devices include, for example, static random-access memory (SRAM) and dynamic random-access memory (DRAM). A DRAM memory cell includes one transistor and one capacitor, thereby providing a high degree of integration. DRAM, however, requires constant refreshing, which limits the use of DRAM to computer main memory. An SRAM memory cell, by contrast, is bi-stable, meaning that it can maintain its state statically and indefinitely, so long as adequate power is supplied. SRAM also supports high speed operation, with lower power dissipation, which is useful for computer cache memory.

Operation of processor architectures involves fetching data from memory, performing certain arithmetic operations, logical operations, etc., and storing the data back into the memory. In practice, multi-level cache architectures are commonly employed for improved performance by exploiting a spatial locality and a temporal locality of the accessed data. For example, the multi-level cache architecture may include a level-one (L1) cache, a level-two (L2) cache, and a level-three (L3) cache. L2/L3 cache memories are commonly implemented using large-size memories (e.g., SRAM), which are accessed using multi-cycle modes. These multi-cycle modes may specify a single cycle setup time on memory input pins of the L2/L3 cache memories. Unfortunately, meeting the single cycle setup time on the input pins of the cache memories is challenging and often limits memory frequency.

During operation, memory read/write access occurs over multiple cycles of a main clock. By contrast, memory inputs such as a write/read address, write data, and control signals are specified to complete in a single cycle. Unfortunately, meeting the single cycle setup time on the input pins of memory is challenging and often limits operation frequency. By contrast, a data read at a memory output is specified for completion within multiple clock cycles (e.g., two clock cycles). Due to the disparity between the single cycle setup time at the memory input pins and the multiple clock cycles at the memory output pins, a memory output path exhibits excess positive slack. For example, the positive slack may be significant (e.g., up to several hundred Pico seconds) at the memory output path.

Various aspects of the present disclosure are directed to borrowing time from an output side of the memory and providing the borrowed time to the input side of the memory. The noted time borrowing techniques enable a frequency uplift and overall timing closure as well as power, performance, and area (PPA) benefits to an input logic cone of the memory. Various aspects of the present disclosure provide a solution for transferring (e.g., borrowing) positive slack from the output side to the input side of the memory. Some implementations push the memory clock to transfer the positive slack that exists on the output side of the memory to the input of the memory by pushing out a memory clock.

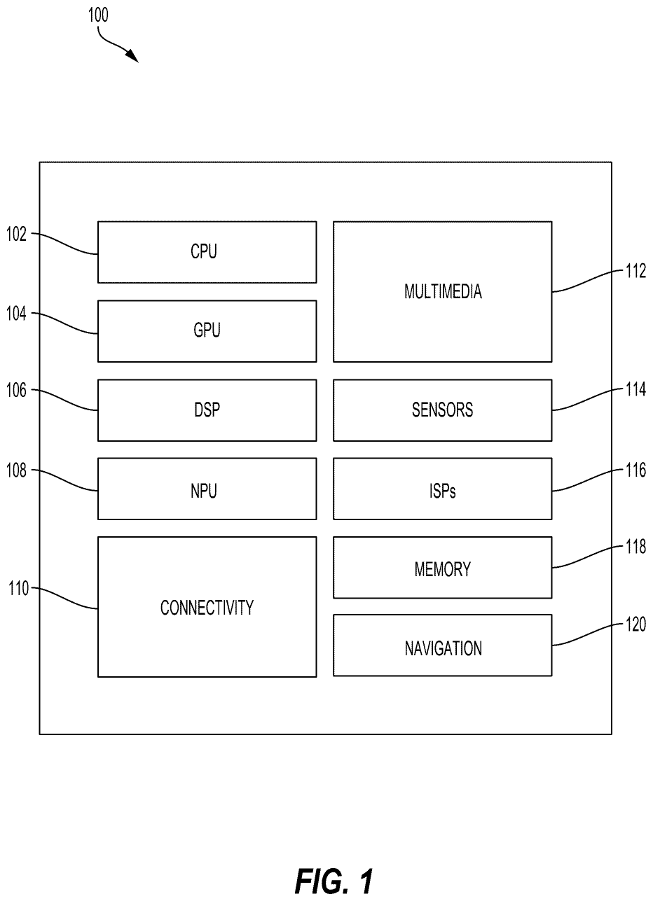

FIG. 1 illustrates an example implementation of a host system-on-chip (SoC) 100, which includes a memory system configured according to a time borrowing memory design, in accordance with aspects of the present disclosure. The host SoC 100 includes processing blocks tailored to specific functions, such as a connectivity block 110. The connectivity block 110 may include sixth generation (6G), connectivity fifth generation (5G) new radio (NR) connectivity, fourth generation long term evolution (4G LTE) connectivity, Wi-Fi connectivity, USB connectivity, Bluetooth® connectivity, Secure Digital (SD) connectivity, and the like.

In this configuration, the host SoC 100 includes various processing units that support multi-threaded operation. For the configuration shown in FIG. 1, the host SoC 100 includes a multi-core central processing unit (CPU) 102, a graphics processor unit (GPU) 104, a digital signal processor (DSP) 106, and a neural processor unit (NPU) 108. The host SoC 100 may also include a sensor processor 114, image signal processors (ISPs) 116, a navigation module 120, which may include a global positioning system, and a memory 118. The multi-core CPU 102, the GPU 104, the DSP 106, the NPU 108, and the multimedia engine 112 support various functions such as video, audio, graphics, gaming, artificial networks, and the like. Each processor core of the multi-core CPU 102 may be an RISC-V machine, an advanced RISC machine (ARM), a microprocessor, or some other type of processor. The NPU 108 may be based on an ARM instruction set.

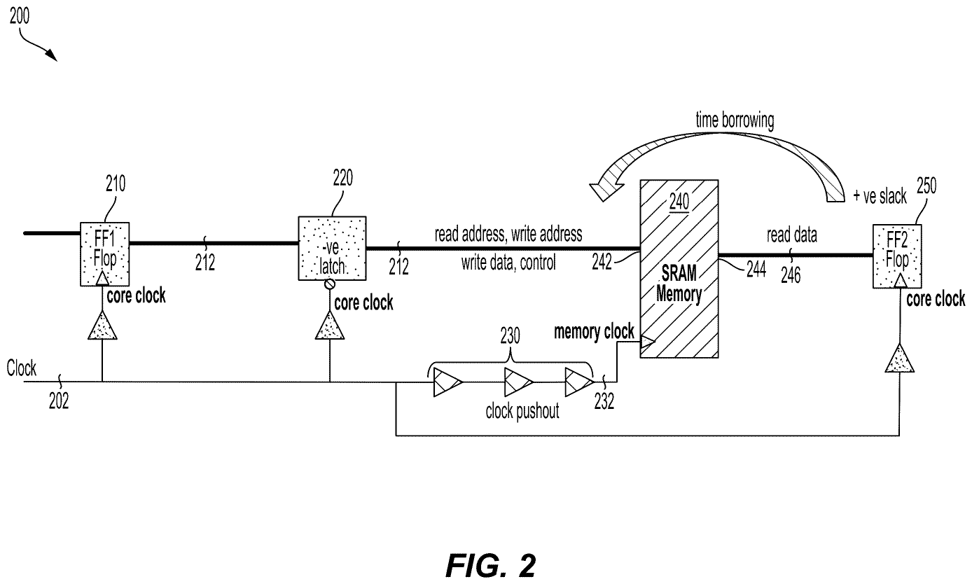

Operation of the host SoC 100 involves fetching data from the memory 118, performing certain arithmetic operations, logical operations, etc., and storing the data back into the memory 118, which is accessed using multi-cycle modes. For example, the memory 118 may be a multi-level cache architecture, including a level-one (L1) cache memory, a level-two (L2) cache memory, and a level-three (L3) cache memory. L2/L3 cache memories are commonly implemented using large-size memories (e.g., static random-access memory (SRAM)) and operate according to the multi-cycle modes. These multi-cycle modes may specify a single cycle setup time on memory input pins of the L2/L3 cache memories. Unfortunately, meeting the single cycle setup time on the input pins of the memory 118 is challenging and often limits memory frequency. Accordingly, there is a need for a time borrowing technique for input cache memory timing paths, for example, as shown in FIG. 2.

FIG. 2 is a block diagram illustrating a memory system 200 configured according to a time borrowing memory design, in accordance with various aspects of the present disclosure. As shown in FIG. 2, the memory system 200 includes a memory 240, which may be implemented as an L2/L3 cache static random-access memory (SRAM). As noted, the memory 240 is configured to operate according to a multi-cycle mode that specifies a single cycle setup time on memory input pins 242 of the memory 240. During operation, memory input 212 (e.g., a write/read address data, write data, and control signals) from a memory input buffer 210 (e.g., a first flip-flop (FF1)) is specified for completing setup on the memory input pins 242 in a single clock cycle.

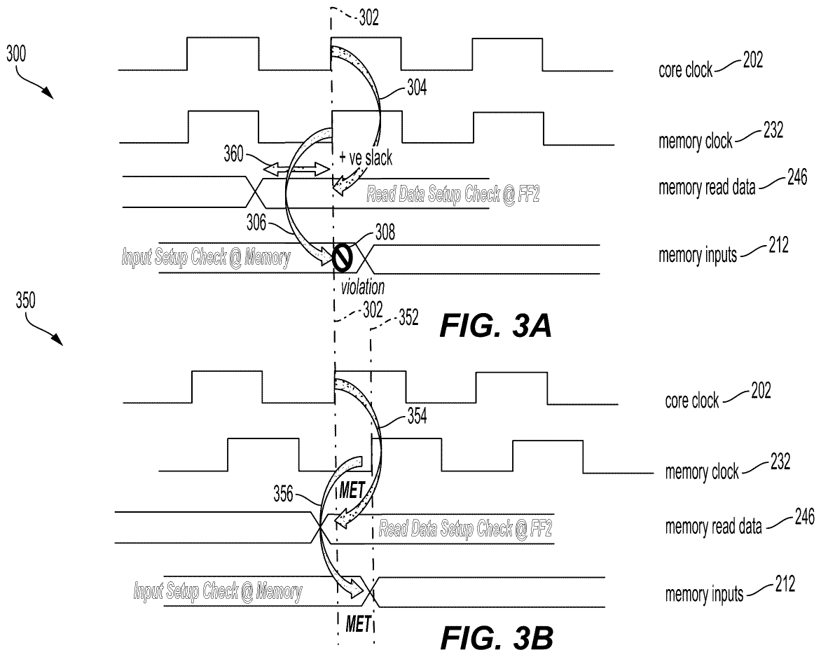

Unfortunately, meeting the single cycle setup time on the memory input pins 242 of the memory 240 is challenging and often limits a frequency of the memory 240. By contrast, setup of memory read data 246 at memory output pins 244 of the memory 240 is specified for completion within a multiple memory cycle (e.g., two or more clock cycles) at a memory output buffer 250 (e.g., a second flip-flop (FF2)). Due to the disparity between the single cycle setup time at the memory input pins 242 and the multiple clock cycles at the memory output pins 244, the memory output pins 244 of the memory 240 exhibit excess positive slack (e.g., up to several hundred Pico seconds). Operation of the memory system 200 is described with references to the timing diagrams shown in FIGS. 3A-5, as follows.

FIGS. 3A and 3B are timing diagrams illustrating time borrowing in cache memory timing paths of the memory system 200 of FIG. 2, according to various aspects of the present disclosure. During operation, the memory input 212 (e.g., a write/read address, write data, and control signals) is specified to complete in a single cycle from the memory input buffer 210 (e.g., flip-flop (FF1)) to memory input pins 242 of the memory 240. Failure to complete setup of the memory input 212 in a single clock cycle results in an input setup time violation, for example, as shown in FIG. 3A.

FIG. 3A is a timing diagram 300 illustrating a memory input setup time violation, according to various aspects of the present disclosure. In the example of FIG. 3A, the timing diagram 300 illustrates waveforms of a core clock 202, a memory clock 232, the memory read data 246, and the memory input 212 relative to a single clock cycle point 302. Additionally, a read data setup check 304 is triggered by the single clock cycle point 302 and is completed prior to the single clock cycle point 302, as shown by a positive slack 360. Conversely, an input data setup check 306 triggered by the single clock cycle point 302 is completed after the single clock cycle point 302, as shown by an input setup time violation 308.

Referring again to FIG. 2, in this implementation, the memory system 200 is configured for borrowing time from the output side of the memory 240 and providing the borrowed time to the input side of the memory 240. In this implementation, the memory system 200 includes clock pushout logic 230 to generate the memory clock 232 as a delayed version of the core clock 202 to a clock input of the memory 240. In this example, the clock pushout logic 230 includes one or more buffers for pushing out the memory clock 232 to transfer the positive setup slack that exists on the output side of the memory 240 to the input side of the memory 240. In particular, the delay integrated into the memory clock 232 prevents the input setup time violation 308 at the memory input pins 242, for example, as shown in FIG. 3B.

FIG. 3B is a timing diagram 350 illustrating time borrowing in cache memory timing paths of the memory system 200 of FIG. 2, according to various aspects of the present disclosure. In this example, the timing diagram 350 also illustrates waveforms of the core clock 202, the memory clock 232, the memory read data 246, and the memory input 212 relative to a single clock cycle point 302 as in the timing diagram 300 of FIG. 3A. The timing diagram 350, however, also illustrates a pushed single clock cycle point 352 of the memory clock 232 generated by the clock pushout logic 230 of FIG. 2.

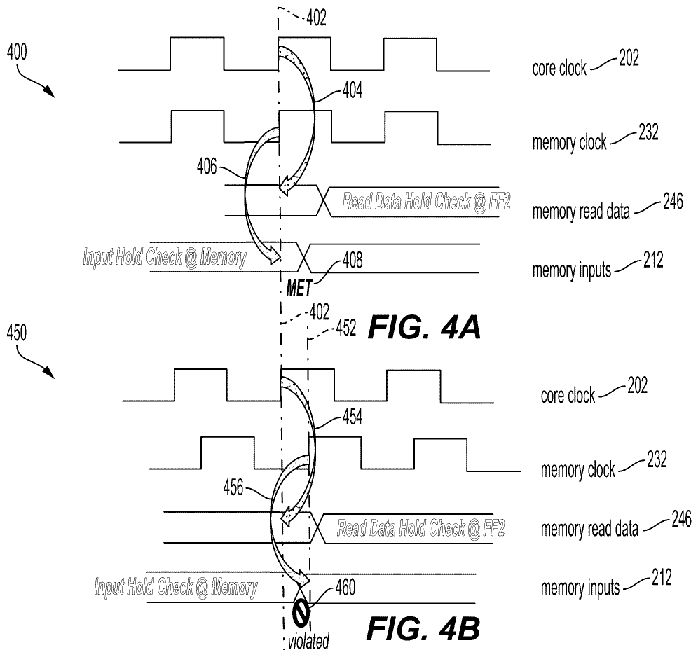

As shown in FIG. 3B, a read data setup check 354 is triggered by the single clock cycle point 302 and completed prior to the single clock cycle point 302. In this example, an input data setup check 356 is triggered by the pushed single clock cycle point 352 and is completed before the pushed single clock cycle point 352. Unfortunately, operation of the clock pushout logic 230 to generate the memory clock 232 may result in a violation of an input hold check (e.g., at hold critical corners) at the memory input pins 242, for example, as illustrated in FIGS. 4A and 4B.

FIGS. 4A and 4B are timing diagrams illustrating time borrowing in cache memory timing paths of the memory system 200 of FIG. 2, according to various aspects of the present disclosure. During operation, the memory input 212 (e.g., a write/read address, write data, and control signals) is specified to a single cycle hold time in the memory input buffer 210 to enable setup at the memory input pins 242 of the memory 240. Failing to hold the memory input 212 until after the single cycle results in a hold time violation (e.g., an overwrite of the memory input 212), for example, as shown in FIG. 4A.

FIG. 4A is a timing diagram 400 illustrating compliance 408 with an input hold check 406 at the memory input pins 242 and a read data hold check 404 at the memory output pins 244 of the memory 240, according to various aspects of the present disclosure. In this example, the timing diagram 400 also illustrates waveforms of the core clock 202, the memory clock 232, the memory read data 246, and the memory input 212 relative to a single clock cycle point 402. Additionally, a read data hold check 404 is triggered by the single clock cycle point 402 and the read data hold is maintained after the single clock cycle point 402. Additionally, an input hold check 406 is triggered by the single clock cycle point 402, and the hold of the memory input 212 is maintained after the single clock cycle point 402.

FIG. 4B is a timing diagram 450 illustrating a memory hold time violation, according to various aspects of the present disclosure. In this example, the timing diagram 450 also illustrates waveforms of the core clock 202, the memory clock 232, the memory read data 246, and the memory input 212 relative to a single clock cycle point 402 as in the timing diagram 400 of FIG. 4A. The timing diagram 450, however, also illustrates a pushed single clock cycle point 452 of the memory clock 232 generated by the clock pushout logic 230 of FIG. 2.

As shown in FIG. 4B, a read data hold check 454 is triggered by the single clock cycle point 402, and the memory read data 246 is maintained after the single clock cycle point 402. In this example, an input data hold check 456 is triggered by the pushed single clock cycle point 452 and the memory inputs are released before the pushed single clock cycle point 452. Unfortunately, operation of the clock pushout logic 230 to generate the memory clock 232 results in a violation 460 of the input hold check (e.g., at hold critical corners), as illustrated in FIG. 4B.

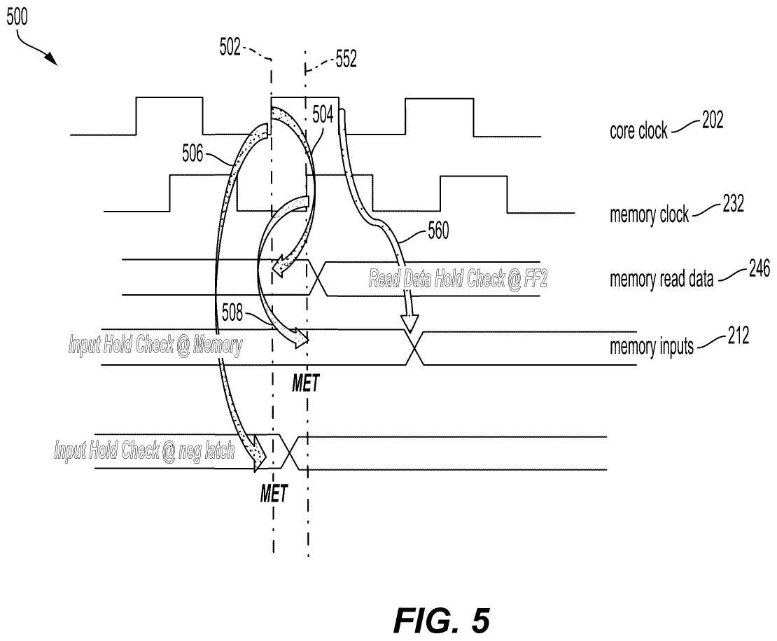

According to various aspects of the present disclosure, a negative latch is provided to ensure the memory input pins 242 are held in a safe state to prevent violation of an input hold check. Referring again to FIG. 2, the memory system 200 is modified to include a latch buffer 220 between the memory input buffer 210 and the memory input pins 242 of the memory 240. In this example, the latch buffer 220 operates according to the core clock 202 to store the memory input 212 prior to setup of the memory input 212 at the memory input pins 242 of the memory 240. In particular, due to the disparity between the core clock 202 and the memory clock 232, the memory input 212 is at risk of being overwritten. Operation of the memory system 200 is further illustrated in FIG. 5.

FIG. 5 is a timing diagram 500 illustrating time borrowing in cache memory timing paths of the memory system 200 of FIG. 2, in accordance with various aspects of the present disclosure. In this example, the timing diagram 500 also illustrates waveforms of the core clock 202, the memory clock 232, the memory read data 246, and the memory input 212 relative to a single clock cycle point 502. The timing diagram 500, however, also illustrates a pushed single clock cycle point 552 of the memory clock 232 generated by the clock pushout logic 230 of FIG. 2.

As shown in FIG. 5, a read data hold check 504 is triggered by the single clock cycle point 502, and the memory read data 246 is maintained after both the single clock cycle point 502 and the pushed single clock cycle point 552. In this example, an input data hold check 506 is triggered by the single clock cycle point 502, and the memory input 212 is maintained in the latch buffer 220 until after the single clock cycle point 502. Additionally, an input data hold check 508 is triggered by the pushed single clock cycle point 552, and the memory input 212 is maintained at the memory input pins 242 of the memory 240 until after the pushed single clock cycle point 552.

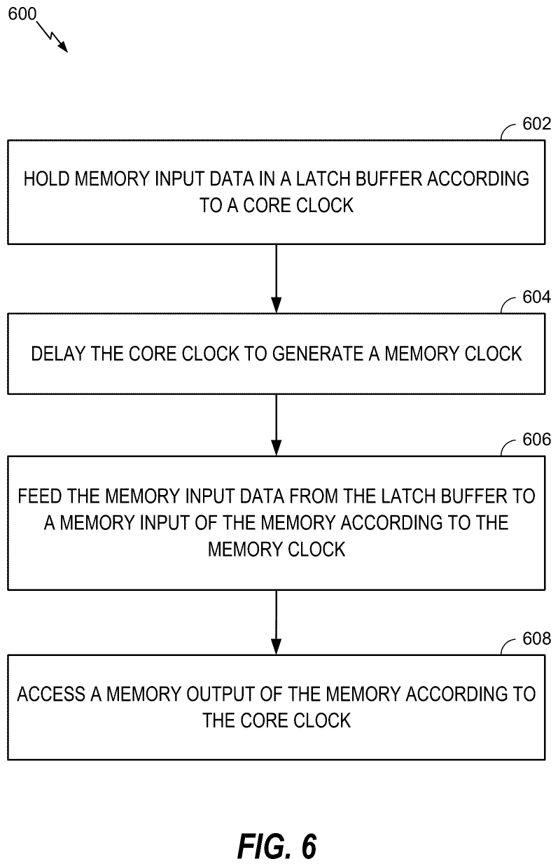

According to various aspects of the present disclosure, introduction of the latch buffer 220 avoids a violation of an input hold check (e.g., at hold critical corners), as illustrated in FIG. 4B. In particular, as shown in FIG. 5, the memory input 212 is held at the input of the memory 240 until a negative clock edge 560 triggers release of the memory input 212. The noted time borrowing techniques enable a frequency uplift and overall timing closure as well as power, performance, and area (PPA) benefits to the memory 240. In this implementation, the latch buffer 220 protects a safe hold of the memory input pins 242 from being overwritten. According to various aspects of the present disclosure, the disclosed time borrowing memory scheme enables improved performance on memory paths, which are critical in L2/L3 cache memory as well as other memory subsystems. A process for performing the time borrowing memory scheme may be performed, for example, as shown in FIG. 6.

FIG. 6 is a process flow diagram illustrating a method 600 for time borrowing in cache memory timing paths of a memory system, according to various aspects of the present disclosure. The method 600 begins at block 602, in which memory input data is held in a latch buffer according to a core clock. For example, as shown in FIG. 5, the read data hold check 504 is triggered by the single clock cycle point 502, and the memory read data 246 is maintained after both the single clock cycle point 502 and the pushed single clock cycle point 552. In this example, the input data hold check 506 is triggered by the single clock cycle point 502, and the memory input 212 is maintained in the latch buffer 220 until after the single clock cycle point 502. Additionally, an input data hold check 508 is triggered by the pushed single clock cycle point 552, and the memory input 212 is maintained at the memory input pins 242 of the memory 240 until after the pushed single clock cycle point 552.

At block 604, the core clock is delayed to generate a memory clock. For example, as shown in FIG. 2, the memory system 200 includes clock pushout logic 230 to generate the memory clock 232 as a delayed version of the core clock 202 to a clock input of the memory 240. In this example, the clock pushout logic 230 includes one or more buffers for pushing out the memory clock 232 to transfer the positive setup slack that exists on the output side of the memory 240 to the input side of the memory 240. In particular, the delay integrated into the memory clock 232 prevents the input setup time violation 308 at the memory input pins 242, for example, as shown in FIG. 3B.

At block 606, the memory input data from the latch buffer is fed to a memory input of the memory according to the memory clock. For example, as shown in FIG. 5, an input data hold check 506 is triggered by the single clock cycle point 502, and the memory input 212 is maintained in the latch buffer 220 until after the single clock cycle point 502. Additionally, an input data hold check 508 is triggered by the pushed single clock cycle point 552, and the memory input 212 is maintained at the memory input pins 242 of the memory 240 until after the pushed single clock cycle point 552.

At block 608, a memory output of the memory is accessed according to the core clock. For example, as shown in FIG. 2, setup of memory read data 246 at memory output pins 244 of the memory 240 is specified for completion within a multiple memory cycle (e.g., two or more clock cycles) at a memory output buffer 250 (e.g., a second flip-flop (FF2)).

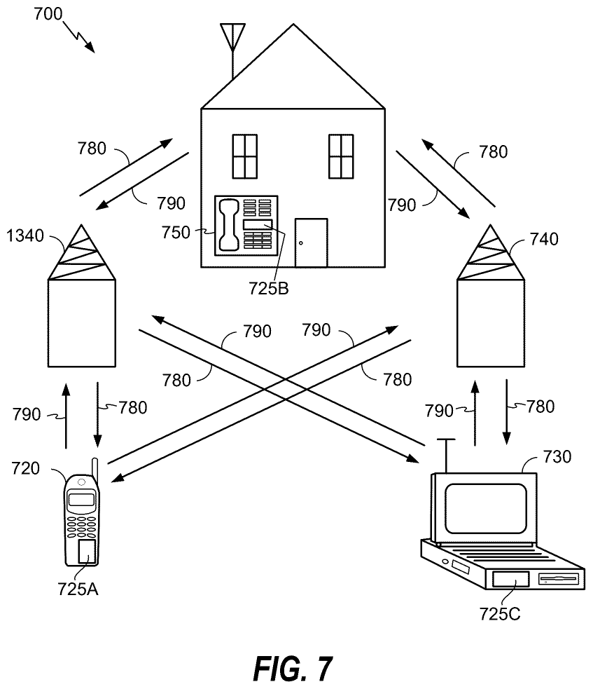

FIG. 7 is a block diagram showing an exemplary wireless communications system 700 in which an aspect of the disclosure may be advantageously employed. For purposes of illustration, FIG. 7 shows three remote units 720, 730, and 750, and two base stations 740. It will be recognized that wireless communications systems may have many more remote units and base stations. Remote units 720, 730, and 750 include IC devices 725A, 725C, and 725B that include the disclosed time borrowing memory design. It will be recognized that other devices may also include the disclosed time borrowing memory design, such as the base stations, switching devices, and network equipment. FIG. 7 shows forward link signals 780 from the base stations 740 to the remote units 720, 730, and 750, and reverse link signals 790 from the remote units 720, 730, and 750 to base stations 740.

In FIG. 7, remote unit 720 is shown as a mobile telephone, remote unit 730 is shown as a portable computer, and remote unit 750 is shown as a fixed location remote unit in a wireless local loop system. For example, the remote units may be a mobile phone, a hand-held personal communications systems (PCS) unit, a portable data unit, such as a personal data assistant, a GPS enabled device, a navigation device, a set top box, a music player, a video player, an entertainment unit, a fixed location data unit, such as meter reading equipment, or other device that stores or retrieves data or computer instructions, or combinations thereof. Although FIG. 7 illustrates remote units according to aspects of the present disclosure, the disclosure is not limited to these exemplary illustrated units. Aspects of the present disclosure may be suitably employed in many devices, which include the disclosed time borrowing memory design.

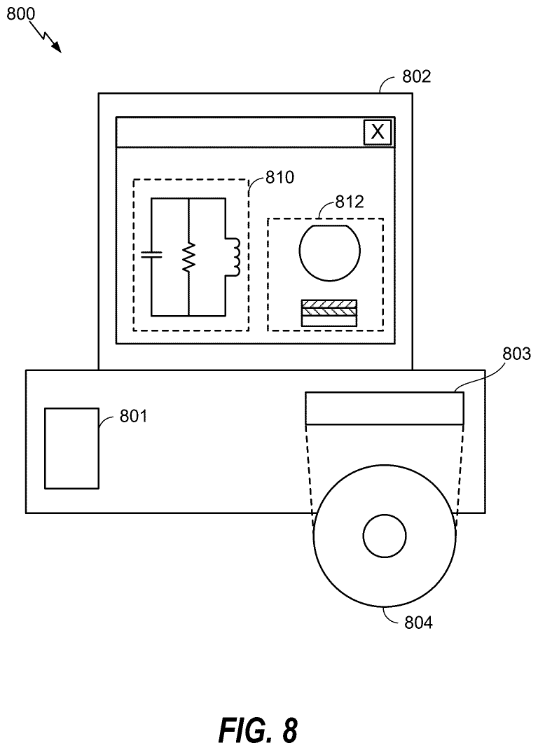

FIG. 8 is a block diagram illustrating a design workstation used for circuit, layout, and logic design of a semiconductor component, such as the memory system configured according to a time borrowing memory design disclosed above. A design workstation 800 includes a hard disk 801 containing operating system software, support files, and design software such as Cadence or OrCAD. The design workstation 800 also includes a display 802 to facilitate design of a circuit 810 or an integrated circuit (IC) component 812 such as a time borrowing memory design. A storage medium 804 is provided for tangibly storing the design of the circuit 810 or the IC component 812 (e.g., the time borrowing memory design). The design of the circuit 810 or the IC component 812 may be stored on the storage medium 804 in a file format such as GDSII or GERBER. The storage medium 804 may be a CD-ROM, DVD, hard disk, flash memory, or other appropriate device. Furthermore, the design workstation 800 includes a drive apparatus 803 for accepting input from or writing output to the storage medium 804.

Data recorded on the storage medium 804 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 804 facilitates the design of the circuit 810 or the IC component 812 by decreasing the number of processes for designing semiconductor wafers.

Implementation examples are described in the following numbered clauses:
1. A method for time borrowing in memory timing paths of a memory, comprising:
   holding memory input data in a latch buffer according to a core clock;
   delaying the core clock to generate a memory clock;
   feeding the memory input data from the latch buffer to a memory input of the memory according to the memory clock; and
   accessing a memory output of the memory according to the core clock.
2. The memory of clause 1, further comprising:
   reading the memory output according to the core clock; and
   storing read data in a memory output buffer.
3. The method of any of clauses 1 or 2, further comprising feeding the core clock to a memory output buffer.
4. The method of any of clauses 1-3, in which holding the memory input data comprises:
   reading the memory input from a memory input buffer according to the core clock; and
   storing the memory input data in the latch buffer according to the core clock.
5. The method of any of clauses 1-4, in which the memory input data comprises a write/read address data, write data, and/or control signals.
6. The method of any of clauses 1-5, in which the memory comprises a level-two (L2) and/or a level-three (L3) cache.
7. The method of any of clauses 1-6, further comprising performing a read data setup check in two clock cycles of the core clock.
8. The method of any of clauses 1-7, in which delaying the core clock comprises latching the core clock at one or more buffers prior to a clock input of the memory.
9. The method of any of clauses 1-8, in which feeding the memory input data comprises completing setup of the memory input data within a single clock cycle of the memory clock.
10. The method of any of clauses 1-9, further comprising performing a read data setup check at the output of the memory prior to an input data setup check at input pins of the memory.
11. A non-transitory computer-readable medium having program code recorded thereon for time borrowing in memory timing paths of a memory, the program code being executed by a processor and comprising:
   program code to hold memory input data in a latch buffer according to a core clock;
   program code to delay the core clock to generate a memory clock;
   program code to feed the memory input data from the latch buffer to a memory input of the memory according to the memory clock; and
   program code to access a memory output of the memory according to the core clock.
12. The non-transitory computer-readable medium of clause 11, further comprising:
   program code to read the memory output according to the core clock; and
   program code to store read data in a memory output buffer.
13. The non-transitory computer-readable medium of any of clauses 11 or 12, further comprising program code to feed the core clock to a memory output buffer.
14. The non-transitory computer-readable medium of any of clauses 11-13, in which the program code to hold the memory input data comprises:
   program code to read the memory input from a memory input buffer according to the core clock; and
   program code to store the memory input data in the latch buffer according to the core clock.
15. The non-transitory computer-readable medium of any of clauses 11-14, in which the memory input data comprises a write/read address data, write data, and/or control signals.
16. The non-transitory computer-readable medium of any of clauses 11-15,in which the memory comprises a level-two (L2) and/or a level-three (L3) cache.
17. The non-transitory computer-readable medium of any of clauses 11-16, further comprising program code to perform a read data setup check in two clock cycles of the core clock.
18. The non-transitory computer-readable medium of any of clauses 11-17, in which the program code to delay the core clock comprises program code to latch the core clock at one or more buffers prior to a clock input of the memory.
19. The non-transitory computer-readable medium of any of clauses 11-18, in which the program code to feed the memory input data comprises program code to complete setup of the memory input data within a single clock cycle of the memory clock.
20. The non-transitory computer-readable medium of any of clauses 11-19, further comprising program code to perform a read data setup check at the output of the memory prior to an input data setup check at input pins of the memory.

For a firmware and/or software implementation, the methodologies may be implemented with modules (e.g., procedures, functions, etc.) that perform the functions described. A machine-readable medium tangibly embodying instructions may be used in implementing the methodologies described. For example, software codes may be stored in a memory and executed by a processor unit. Memory may be implemented within the processor unit or external to the processor unit. As used, the term “memory” refers to types of long term, short term, volatile, nonvolatile, or other memory and is not limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include RAM, ROM, EEPROM, CD-ROM or other optical disk storage, magnetic disk storage or other magnetic storage devices, or other medium that can be used to store desired program code in the form of instructions or data structures and that can be accessed by a computer. Disk and disc, as used, include compact disc (CD), laser disc, optical disc, digital versatile disc (DVD), floppy disk and Blu-ray® disc, where disks usually reproduce data magnetically, while discs reproduce data optically with lasers. Combinations of the above should also be included within the scope of computer-readable media.

In addition to storage on computer-readable medium, instructions and/or data may be provided as signals on transmission media included in a communications apparatus. For example, a communications apparatus may include a transceiver having signals indicative of instructions and data. The instructions and data are configured to cause one or more processors to implement the functions outlined in the claims.

Although the present disclosure and its advantages have been described in detail, various changes, substitutions, and alterations can be made without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above, and below may refer to sides of a substrate or electronic device. Moreover, the scope of the present application is not intended to be limited to the configurations of the process, machine, manufacture, composition of matter, means, methods, and steps described in the specification. As one of ordinary skill in the art will readily appreciate from the disclosure, processes, machines, manufacture, compositions of matter, means, methods, or steps, presently existing or later to be developed that perform the same function or achieve the same result as the corresponding configurations described may be utilized according to the present disclosure. Accordingly, the appended claims are intended to include within their scope such processes, machines, manufacture, compositions of matter, means, methods, or steps.

Those of skill would further appreciate that the various illustrative logical blocks, modules, circuits, and algorithm steps described in connection with the disclosure may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the application and design constraints imposed on the overall system. Skilled artisans may implement the described functionality in varying ways for each application, but such implementation decisions should not be interpreted as causing a departure from the scope of the present disclosure.

The various illustrative logical blocks, modules, and circuits described in connection with the disclosure may be implemented or performed with a general-purpose processor, a digital signal processor (DSP), an application specific integrated circuit (ASIC), a field programmable gate array (FPGA), or other programmable logic device, discrete gate or transistor logic, discrete hardware components, or any combination thereof designed to perform the functions described. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, multiple microprocessors, one or more microprocessors in conjunction with a DSP core, or any other such configuration.

The steps of a method or algorithm described in connection with the disclosure may be embodied directly in hardware, in a software module executed by a processor, or in a combination of the two. A software module may reside in RAM, flash memory, ROM, EPROM, EEPROM, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

The previous description of the disclosure is provided to enable any person skilled in the art to make or use the disclosure. Various modifications to the disclosure will be readily apparent to those skilled in the art, and the generic principles defined may be applied to other variations without departing from the spirit or scope of the disclosure. Thus, the disclosure is not intended to be limited to the examples and designs described but is to be accorded the widest scope consistent with the principles and novel features disclosed.

What is claimed is:

1. A method for time borrowing in memory timing paths of a memory, comprising:
holding memory input data in a latch buffer according to a core clock;
delaying the core clock to generate a memory clock;
feeding the memory input data from the latch buffer to a memory input of the memory according to the memory clock; and
accessing a memory output of the memory according to the core clock.

2. The memory of claim 1, further comprising:
reading the memory output according to the core clock; and
storing read data in a memory output buffer.

3. The method of claim 1, further comprising feeding the core clock to a memory output buffer.

4. The method of claim 1, in which holding the memory input data comprises:
reading the memory input from a memory input buffer according to the core clock; and
storing the memory input data in the latch buffer according to the core clock.

5. The method of claim 1, in which the memory input data comprises a write/read address data, write data, and/or control signals.

6. The method of claim 1, in which the memory comprises a level-two (L2) and/or a level-three (L3) cache.

7. The method of claim 1, further comprising performing a read data setup check in two clock cycles of the core clock.

8. The method of claim 1, in which delaying the core clock comprises latching the core clock at one or more buffers prior to a clock input of the memory.

9. The method of claim 1, in which feeding the memory input data comprises completing setup of the memory input data within a single clock cycle of the memory clock.

10. The method of claim 1, further comprising performing a read data setup check at the output of the memory prior to an input data setup check at input pins of the memory.

11. A non-transitory computer-readable medium having program code recorded thereon for time borrowing in memory timing paths of a memory, the program code being executed by a processor and comprising:
program code to hold memory input data in a latch buffer according to a core clock;
program code to delay the core clock to generate a memory clock;
program code to feed the memory input data from the latch buffer to a memory input of the memory according to the memory clock; and
program code to access a memory output of the memory according to the core clock.

12. The non-transitory computer-readable medium of claim 11, further comprising:
program code to read the memory output according to the core clock; and
program code to store read data in a memory output buffer.

13. The non-transitory computer-readable medium of claim 11, further comprising program code to feed the core clock to a memory output buffer.

14. The non-transitory computer-readable medium of claim 11, in which the program code to hold the memory input data comprises:
program code to read the memory input from a memory input buffer according to the core clock; and
program code to store the memory input data in the latch buffer according to the core clock.

15. The non-transitory computer-readable medium of claim 11, in which the memory input data comprises a write/read address data, write data, and/or control signals.

16. The non-transitory computer-readable medium of claim 11, in which the memory comprises a level-two (L2) and/or a level-three (L3) cache.

17. The non-transitory computer-readable medium of claim 11, further comprising program code to perform a read data setup check in two clock cycles of the core clock.

18. The non-transitory computer-readable medium of claim 11, in which the program code to delay the core clock comprises program code to latch the core clock at one or more buffers prior to a clock input of the memory.

19. The non-transitory computer-readable medium of claim 11, in which the program code to feed the memory input data comprises program code to complete setup of the memory input data within a single clock cycle of the memory clock.

20. The non-transitory computer-readable medium of claim 11, further comprising program code to perform a read data setup check at the output of the memory prior to an input data setup check at input pins of the memory.
